(19) United States
(12) Patent Application Publication
(10) Pub. No.: US 2007/0284693 A1
(43) Pub. Date: Dec. 13, 2007

(54) ELECTRICALLY PROGRAMMABLE FUSE WITH ASYMMETRIC STRUCTURE

(75) Inventors: Deok-Kee Kim, Bedford Hills, NY (US); Byeongju Park, Poughkeepsie, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/423,181

(22) Filed: Jun. 9, 2006

(51) Int. Cl. H01L 29/00

(52) U.S. Cl. 257/529

(57) ABSTRACT

An electrically programmable fuse is provided which includes a cathode, an anode, and a fuse link conductively connecting the cathode to the anode. The cathode, the anode and the fuse link each have a length in a direction of current between the anode and cathode. Each of the cathode, the anode and the fuse link also has a width in a direction transverse to the respective length. At a cathode junction where the cathode meets the fuse link, the width of the fuse link decreases substantially and abruptly relative to the width of the cathode. The width of the fuse link increases only gradually in a direction towards an anode junction where the fuse link meets the anode.

### BACKGROUND OF THE INVENTION

This invention relates to microelectronics and more particularly to electrically programmable fuses for inclusion in microelectronic elements.

In recent years, breakthrough chip morphing technology has enabled a new class of semiconductor products that can monitor and adjust their functions to improve their quality, performance and power consumption without any or little human intervention. Software algorithms and microscopic fuses are utilized together to regulate and adapt the operation of the chip in response to changing conditions and system demands. In addition, this approach is becoming more prevalent as it allows the designers to optimize and tailor the performance and capabilities of a chip to meet individual needs of their clients.

Some chips include circuitry which can be altered during the chip's operating lifetime to increase performance, such as to manage power consumption or to address problems such as unanticipated defects that occur along the way. When a performance shortfall or problem is detected, electrical fuses can be programmed to address the problem.

Electrically programmable fuses (“e-fuses”) in microelectronic devices can be used to store information and make or break more or less permanent conductive interconnections within a chip. Fuses can also be used to replace defective circuit elements or system elements with replacement (redundancy) elements, to store information identifying the particular chip on which they are used, and even to adjust the speed of a circuit, such as by making or breaking connections to adjust a total resistance of a path of current through a circuit.

Currently available e-fuses are not usable in some chips that are fabricated in certain process technologies for a variety of reasons. For example, it may not be possible to achieve voltage and current levels required to program such fuses within the amount of time allotted for that purpose.

Each e-fuse typically includes a cathode, an anode and a fuse link which conductively connects the cathode to the anode. To program the e-fuse, electromigration must be produced in the fuse to a sufficient extent to change the e-fuse to a high resistance state.

Two particular e-fuse structures are of interest for discussion in relation to embodiments of the invention below. In each of these cases, the e-fuse structure has not been built for the purpose of assuring that it can be programmed reliably. It is further desirable to reduce the current, voltage and/or amount of time required to program an e-fuse while assuring that the e-fuse is reliably programmed.

A top-down plan view of a fuse structure in accordance with the prior art is illustrated in FIG. 1. As illustrated therein, the fuse 10 includes a cathode 12, an anode 14 and a fuse link 16 extending between the cathode and the anode. The fuse link and the cathode and anode of the fuse are distinguished from each other by their geometry, i.e., the width of the fusible material in the direction of a current used to program the fuse. Also, the cathode and the anode are each contacted from above by conductive vias (not shown) of the microelectronic or semiconductor chip in which the fuse structure is provided. In this example, the junctions 18, 20 between the fuse link 16 and the cathode and anode are not abrupt. Here, at junction 18 with the cathode, the fuse link 16 has the same width 24 as the width of the cathode 12. The fuse link 16 can be considered to include three portions: a first neck 28 connected directly to the cathode, a narrow link 30 connected to the first neck, and a second neck 32 connected between the narrow link 30 and the anode.

The width of the first neck 28 gradually decreases until it reaches a final width 22 in the narrow link 30 portion of the fuse link. The width of the fuse link remains constant at the final width 22 throughout the narrow link 30. Then, the width increases gradually again throughout the second neck, from the end of the narrow link until the junction between the second neck 32 and the anode. At such junction with the anode, the second neck is then as wide as the width 26 of the anode. Here again, the width of the fuse link again does not change abruptly between the fuse link 16 and the anode.

One problem with the fuse 10 illustrated in FIG. 1 is that the first neck 28 provides a relatively large area for electromigration of metals caused by programming the fuse. Among a large number of fuses of this type on a substrate which can be programmed from one state to another, there is a probability that electromigration during the blowing of the fuse will cause the first neck 28 of some programmed fuses to provide a low-resistance path to the fuse link. Such electromigration can be referred to as “neck back-filling”. Because of neck back-filling, circuitry for sensing the state of the fuse sometimes does not sense a correct result when the fuse has been programmed, i.e., blown.

In another prior art fuse structure illustrated in FIG. 2, the junction between the fuse link 52 and the anode 60 is marked by an abrupt change in width 54. The fuse link 52 has uniform narrow width 54 extending between the junction 56 with the cathode 70 and a second junction 58 between the fuse link 52 and the anode 60. The uniform narrow width 54 of the fuse link and the abruptness of the junctions between the cathode and anode and the fuse link tend to cause silicon to diffuse in a direction from the anode 60 towards the cathode 70. As the percentage amount of silicon in the fuse link increases, it becomes progressively less likely that a void will form at a particular location along the fuse link. After blowing the fuse 50, instead of the fuse exhibiting an electrical discontinuity due to formation of a void, a silicon-rich material can remain to provide a conductive path having relatively low resistance.

### SUMMARY OF THE INVENTION

According to one embodiment of the invention, an electrically programmable fuse is provided which includes a cathode, an anode, and a fuse link conductively connecting the cathode to the anode. The cathode, the anode and the fuse link each has a length in a direction of current between the anode and cathode. Each of the cathode, the anode and the fuse link also has a width in a direction transverse to the respective length. At a cathode junction where the cathode meets the fuse link, the width of the fuse link decreases substantially and abruptly relative to the width of the cathode. The width of the fuse link increases only gradually in a direction towards an anode junction where the fuse link meets the anode.

Preferably, the substantial abrupt decrease in the width of the fuse link provides an abrupt electromigration start. The gradual increase in the width of the fuse link provides a gradual electromigration stop for the fuse.

### BRIEF DESCRIPTION OF THE DRAWINGS

FIG. 1 is a top down view illustrating a first prior art electrical fuse.

FIG. 2 is a top down view illustrating a second prior art electrical fuse.

FIG. 3 is a top down view illustrating an electrical fuse in accordance with a first embodiment of the invention.

FIG. 4 is a corresponding sectional view illustrating the electrical fuse of FIG. 3.

FIG. 5A is a schematic diagram illustrating a circuit connection of the fuse illustrated in FIGS. 3 and 4.

FIG. 5B is a timing diagram illustrating a voltage used to program or blow a fuse as illustrated in FIGS. 3 and 4.

FIG. 6 is a top down view illustrating an electrical fuse according to a particular embodiment of the invention.

FIG. 7 is a top down view illustrating an electrical fuse according to a variation of the embodiment of the invention illustrated in FIG. 6.

FIG. 8 is a top down view illustrating an electrical fuse according to a further variation of the embodiment of the invention illustrated in FIG. 6.

FIG. 9 is a top down view illustrating an electrical fuse according to a further embodiment of the invention.

FIG. 10 is a top down view illustrating an electrical fuse according to a variation of the embodiment of the invention illustrated in FIG. 9.

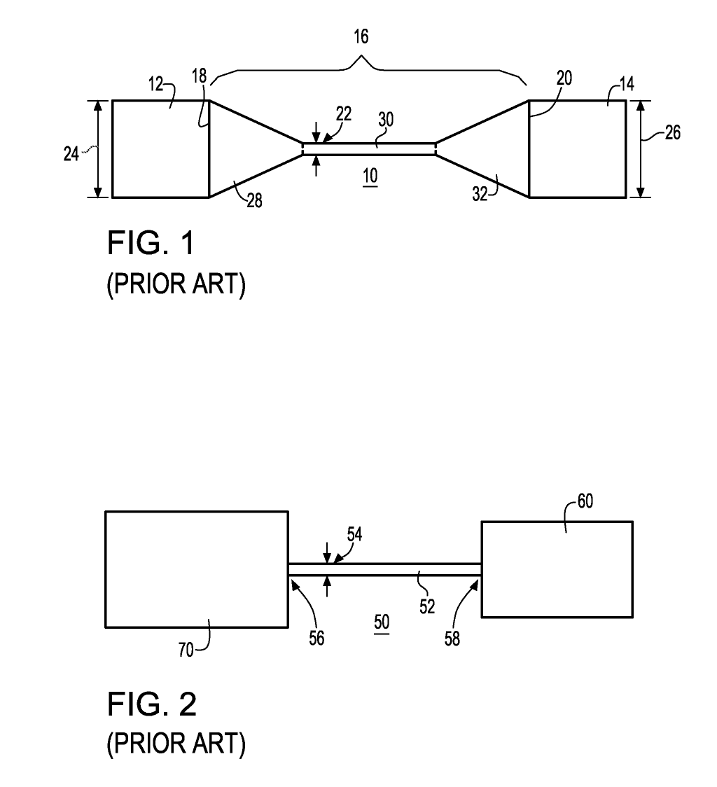

### DETAILED DESCRIPTION

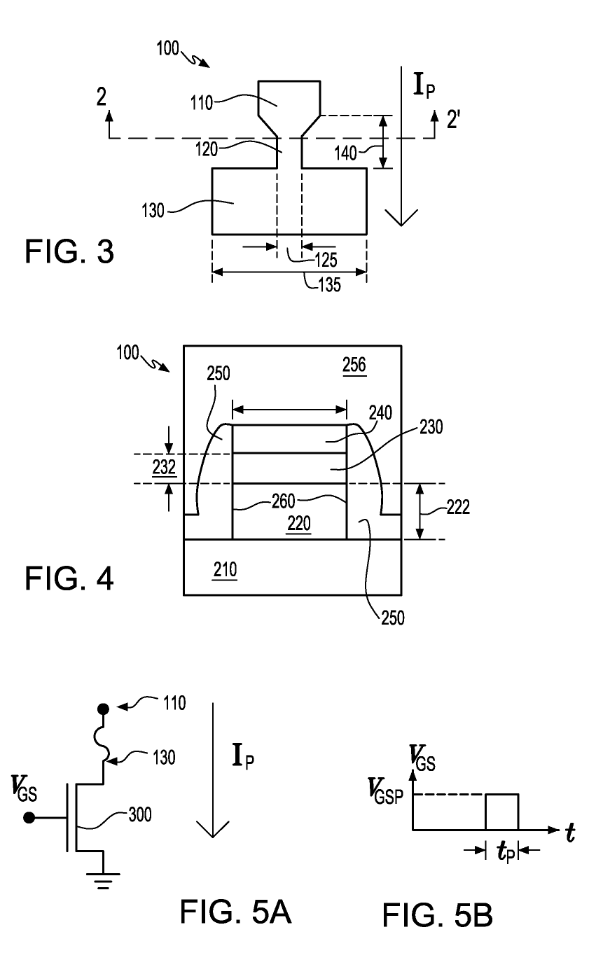

FIGS. 3 and 4 are a top-down view and a corresponding sectional view of an electrical fuse in accordance with an embodiment of the invention. The fuse illustrated in FIGS. 3 and 4, as well as all other fuses shown and described herein, is provided on a microelectronic element, e.g., a chip which includes integrated active semiconductor devices such as transistors, semiconductor diodes, etc. Alternatively, the fuse can be provided on an integrated passives chip, such as may include a relatively large number of passive devices (for example, resistors, capacitors, inductors and/or such fuses) integrated together on the chip.

FIGS. 3 and 4 illustrate a fuse in the unblown state, prior to having electrically programmed the fuse to a blown state. As illustrated therein, the fuse 100 includes a cathode 130 and an anode 110 conductively connected to the cathode by a fuse link 120 of length 140. When the fuse is programmed, the direction of current flow is from the anode 110 towards the cathode 130, also as illustrated. The width of the cathode 135 is greater than the width 125 of the fuse link. In the exemplary fuse illustrated in FIGS. 3 and 4, the width 125 of the fuse link is preferably less than or equal to about 120 nm.

As illustrated in FIG. 4, the fuse can be implemented with a structure including a multi-layer gate stack. The gate stack includes a layer of doped polysilicon 220 and a layer of silicide 230 overlying the silicide layer. In one embodiment, the doped polysilicon layer 220 is doped p+ and is disposed overlying an isolation region. The isolation region can be, for example, a shallow trench isolation (“STI”) region formed, for example, by etching a trench into a substrate, e.g., a silicon substrate or a silicon-on-insulator (“SOI”) layer of a substrate and then filling the resulting trench with an oxide, such as by a high density plasma (“HDP”) deposition. Alternatively, the isolation region can be formed by forming a field oxide at a major surface of a silicon substrate by local oxidation of silicon (“LOCOS”).

Preferably, as further illustrated in FIG. 4, an optional dielectric cap layer 240 overlies the silicide layer 230, the cap layer preferably including a material such as silicon nitride. Preferably, dielectric spacers 250 are also provided which overlie and extend outward from sidewalls 260 of the silicon layer 220 and silicide layer 230.

An interlevel dielectric (“ILD”) layer 256 is provided, overlying the silicide layer 230 and optional nitride cap layer 240. The ILD layer can have a planarizing function, acting to flatten topography in relation to the topography of the fuse structure 100. For that purpose, a planarizing dielectric such as doped or undoped silicate glass, e.g., borophosphosilicate glass (BPSG), spin-on-glass, or an organic dielectric can be provided. In a preferred embodiment such as illustrated in FIG. 2, the thickness of the silicide layer is preferably about 30 nm. The thickness 222 of the doped polysilicon layer 220 is preferably around 150 nm.

In an exemplary method of fabricating the fuse 100, the isolation region 210 is formed, after which a layer 220 of polysilicon is deposited, followed by a layer of metal, e.g., nickel, titanium, tungsten, titanium-tungsten, platinum, palladium, cobalt, among others or a combination of one or more of such metals, which is capable of forming a silicide with the polysilicon. A dielectric layer, preferably including silicon nitride, is then deposited as a cap layer 240 covering the metal layer. The cap layer is then patterned with the metal layer and polysilicon layer to form a structure having the desired contour and dimensions of the fuse as shown in FIG. 3. Thereafter, one or more dielectric layers are deposited and patterned to form the spacers 250. At some point, the metal layer is converted at least partially to a silicide layer 230 by reacting the metal therein with the polysilicon in layer 220. An interlevel dielectric layer (ILD) 256 is formed to overlie the fuse 100 and contact vias to the fuse are made through openings in the ILD 256.

FIG. 5A is a schematic illustrating connection of the electrical fuse 100 illustrated in FIGS. 3 and 4 within a circuit capable of programming the fuse 100. As illustrated therein, a programming current Iₚ flows in a direction from a voltage source (Vfsource) through the anode 110 and towards the cathode 130 when a programming transistor 300 is biased properly for conduction by a biasing voltage V_{GS} having an appropriate value. As further illustrated in FIG. 5B, the fuse is programmable by raising the biasing voltage V_{GS} to a proper value V_{GSP} and maintaining it for a sufficient programming time phase tₚ. In a particular example, the programming time phase tₚ has a duration of about 200 μs.

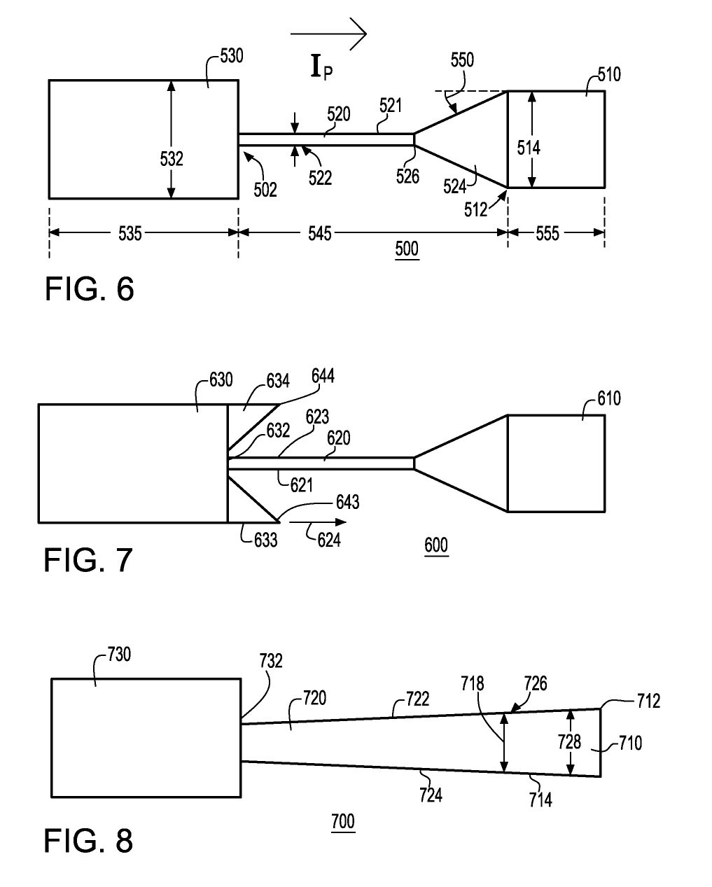

A fuse 500 in accordance with a particular embodiment of the invention will now be described with reference to the top-down plan view of FIG. 6. As illustrated therein, in the as yet unblown state the fuse 500 includes a cathode 530 to which a fuse link 520 is conductively connected at a cathode junction 502. At another end of the fuse link 520 opposite from the cathode 530, the fuse link 520 conductively connects to an anode 510 at an anode junction 512. In a direction of a programming current Iₚ which can be applied to the fuse 500, the cathode has length 535, the fuse link has length 545 and the anode has length 555.

In the fuse 500 illustrated in FIG. 6, the cathode junction 502 is marked by a substantial and abrupt decrease in the width 522 of the fuse link 520 in relation to the width 532 of the cathode. On the other hand, in a direction from the fuse link 520 towards the anode 510, the width 522 of the fuse link increases only gradually.

In the particular structure illustrated in FIG. 6, the fuse link includes a first segment 521 which begins at the cathode junction, extending for a portion of the length 545 of the fuse link. Preferably, the width 522 of the first segment 521 of the fuse link stays constant from one end of the first segment at the cathode junction to the other end where the first segment meets the neck 524. The width of the fuse link then gradually increases from the width 522 of the first segment at a first end 526 of the neck 524 to the width 514 of the anode 510 at the anode junction 512. The neck 524, which can also be referred to as a second segment, has width which preferably increases monotonically from the first end 526 to the anode 510. Moreover, preferably, the peripheral edge of the neck does not make a large angle in relation to a peripheral edge of the anode to which it is joined. Preferably, such angle is less than 45 degrees.

The abrupt decrease in width at the cathode junction of the fuse link relative to the cathode provides an abrupt start location for electromigration during the programming of the fuse. The abrupt start location assures that high current crowding and temperature gradient is present for blowing the fuse. On the other hand, the gradual increase in the width of the fuse link 520 in the direction from the cathode towards the anode 510 provides a gradual stop location for the electromigration of metals during the programming of the fuse. The gradual stop location also assists in keeping the electromigrated material from going into the anode and, hence, assures that most of the fuse link becomes free of metal when blowing the fuse.

FIG. 8 illustrates a fuse 700 in accordance with a variation of the embodiment described with reference to FIGS. 6 and 7. In such variation, peripheral edges 712, 714 of the anode 710 are continuous, i.e., collinear, with corresponding peripheral edges 722, 724, respectively, of the fuse link. Preferably, the peripheral edges 722, 724 of the fuse link 720 are continuous and straight from the abrupt cathode junction 732 with the cathode 730 up to the anode junction 726 with the anode. In this case, the anode junction 726 between the fuse link 720 and the anode 710 is not identified by a particular geometrical feature. Rather, the location of the anode junction 726 is identified by the width 718 that the fuse link reaches at the anode junction 726. The width 718 at the anode junction 726 is at or close to the width 728 of the anode at its largest, final width.

In a particular embodiment as illustrated in FIG. 7, extension portions 633, 634 of the cathode 630 extend beyond the cathode junction 632 in a direction 624 towards the anode 610. Preferably, extension portions 633, 634 extend parallel to the fuse link 620. Preferably, a first portion 633 of the cathode 630 extends adjacent to a first peripheral edge 621 of the fuse link 620 and second portion 634 of the cathode 630 extends adjacent to a second peripheral edge 623 of the fuse link 620, the second peripheral edge 623 being remote from the first peripheral edge, i.e., widthwise across from the first peripheral edge. In the particular example illustrated in FIG. 7, each of the extension portions 633, 634 has a tip 643, 644, respectively. In addition, from the cathode junction 632, the widths of the extension portions decrease monotonically between the cathode junction and the tips.

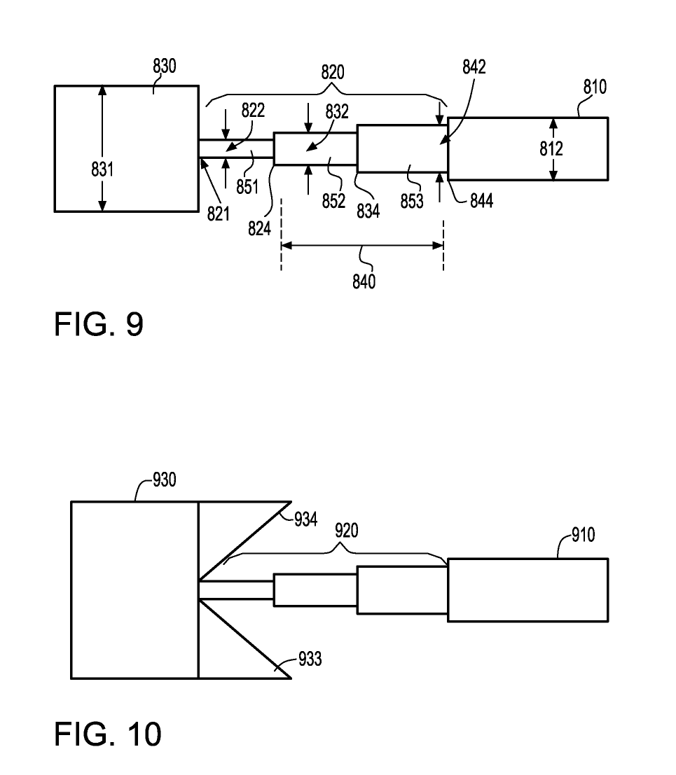

A fuse structure in accordance with another embodiment of the invention will now be described with reference to FIG. 9. In the particular example illustrated therein, the fuse link portion 820 of a fuse 800 has width which increases stepwise between a first segment 851 having an initial width 822 and the anode 810 having a final width 812. The first segment has an initial width 822 which is a substantial and abrupt decrease in width from the width 831 of the cathode 830.

As further illustrated in FIG. 9, the width 822 of the fuse link 820 increases by a first step increase at a junction 824 between a first segment 851 of the fuse link and a second segment 852. The junction 824 occurs at a first location which preferably has a distance 840 from the anode junction 844 which is greater than half the length of the fuse link 820, i.e., greater than half the distance between the cathode junction 821 and the anode junction 844. Then, again the width 832 of the fuse link 820 increases by a second step increase at a junction 834 between the second segment 852 and a third segment 853. Finally, the width 842 of the fuse link 820 increases by a third step increase at the anode junction 844 between the third segment 853 and the anode 810. Preferably, the first segment 851 has constant width 822, the second segment 852 has a constant but different width 832 and the third segment 853 has another constant but different width 842. In a particular embodiment, segments of the fuse link, e.g., the second segment and the third segment, each have length greater than about 10% of the length of the fuse link.

FIG. 10 illustrates a further variation in which the cathode 930 includes extension portions 933, 934 as shown and described above with respect to FIG. 7, and the width of the fuse link 920 increases stepwise between the cathode and the anode 910 as shown and described above with respect to FIG. 9.

The particular fuse geometries shown and described above with respect to FIG. 3 and FIGS. 6 through 10 can be utilized with fuses having different material compositions than the polysilicon and silicon structure shown in FIG. 4. In one variation, the polysilicon layer 220 can be omitted and the fuse can consist essentially of silicide material. In a second variation, the polysilicon layer 220 can be omitted and the fuse can include the silicide layer 230 and another layer overlying or underlying the silicide layer, such other layer consisting essentially of one or more metals and/or one or more conductive compounds of metals. In such second variation, such layer can include, for example, one or more of tantalum nitride (TaN), titanium nitride (TiN) or tungsten (W). In a third variation, both the polysilicon layer 220 and the silicide layer 230 are omitted and the fuse can include a layer consisting essentially of one or more metals and/or one or more conductive compounds of metals, such as, by way of example, TaN, TiN or W.

While the invention has been described in accordance with certain preferred embodiments thereof, those skilled in the art will understand the many modifications and enhancements which can be made thereto without departing from the true scope and spirit of the invention, which is limited only by the claims appended below.

What is claimed is:

1. A microelectronic element including an electrically programmable fuse, comprising:
a cathode;
an anode; and
a fuse link conductively connecting the cathode to the anode, the cathode, the anode and the fuse link each having a length in a direction of current between the anode and cathode, each of the cathode, the anode and the fuse link having a width in a direction transverse to the respective length,
wherein the width of the fuse link decreases substantially and abruptly relative to the width of the cathode at a cathode junction where the cathode meets the fuse link, and the width of the fuse link increases only gradually in a direction towards an anode junction where the fuse link meets the anode.

2. The microelectronic element as claimed in claim 1, wherein the substantial abrupt decrease in the width of the fuse link provides an abrupt start location for electromigration during programming of the fuse and the gradual increase in the width of the fuse link provides a gradual stop location for electromigration during the programming of the fuse.

3. The microelectronic element as claimed in claim 1, the fuse link includes a first segment beginning at the cathode junction extending for a portion of a length of the fuse link, wherein the width of the segment is constant throughout the length of the segment.

4. The microelectronic element as claimed in claim 3, wherein the fuse link further comprises a second segment extending from the first segment in a direction towards the anode, wherein a width of the second segment increases monotonically in the direction towards the anode junction.

5. The microelectronic element as claimed in claim 4, wherein a peripheral edge of the anode defines a first line and a peripheral edge of the fuse link meets the line at the anode junction at an angle of less than 45 degrees.

6. The microelectronic element as claimed in claim 1, wherein peripheral edges of the fuse link and the anode are collinear at the anode junction.

7. The microelectronic element as claimed in claim 6, wherein the fuse link includes a metal silicide.

8. The microelectronic element as claimed in claim 4, wherein the cathode includes a first portion extending beyond the cathode junction in a direction towards the anode junction.

9. The microelectronic element as claimed in claim 8, wherein the first portion of the cathode extends beyond the cathode junction adjacent to a first peripheral edge of the fuse link, the cathode further including a second portion extending beyond the junction adjacent to a second peripheral edge of the fuse link, the second peripheral edge being remote from the first peripheral edge.

10. The microelectronic element as claimed in claim 9, wherein each of the first and second portions has a tip remote from the cathode junction, wherein a width of each of the first and second portions decreases monotonically between the cathode junction and the tip.

11. The microelectronic element as claimed in claim 3, wherein the width of the fuse link increases by a first step increase at a first location spaced from the anode junction.

12. The microelectronic element as claimed in claim 11, wherein the width of the fuse link increases by a second step increase at a second location between the first location and the anode junction.

13. The microelectronic element as claimed in claim 12, wherein a distance between the first location and the anode junction is at least half the length of the fuse link.

14. The microelectronic element as claimed in claim 13, wherein the width of the fuse link is constant between the first location and the second location.

15. The microelectronic element as claimed in claim 14, wherein a distance between the first location and the second location is greater than 10% of a length of the fuse link.

16. The microelectronic element as claimed in claim 11, wherein the width of the anode increases by a third step increase from a width of the fuse link at the anode junction.

17. A method of forming an electrically programmable fuse of a microelectronic element, comprising:
forming a cathode, an anode, and a fuse link conductively connecting the cathode to the anode, the cathode, the anode and the fuse link each having a length in a direction of current between the anode and cathode, each of the cathode, the anode and the fuse link having a width in a direction transverse to the respective length, wherein the width of the fuse link decreases substantially and abruptly relative to the width of the cathode at a cathode junction where the cathode meets the fuse link, and the width of the fuse link increases only gradually in a direction towards an anode junction where the fuse link meets the anode.

18. The method as claimed in claim 17, wherein the fuse link includes a first segment beginning at the cathode junction extending for a portion of a length of the fuse link, wherein the width of the segment is constant throughout the length of the segment.

19. The method as claimed in claim 18, wherein the fuse link further comprises a second segment extending from the first segment in a direction towards the anode, wherein a width of the second segment increases monotonically in the direction towards the anode junction.

20. The method as claimed in claim 19, wherein a peripheral edge of the anode defines a first line and a peripheral edge of the fuse link meets the line at the anode junction at an angle of less than 45 degrees.
